(19) United States
(12) Patent Application Publication
(10) Pub. No.: US 2025/0231899 A1
(43) Pub. Date: Jul. 17, 2025

(54) MEMORY DEVICE

(71) Applicant: Samsung Electronics Co., Ltd., Suwon-si (KR)

(72) Inventors: JEONGHYEON CHO, Suwon-si (KR); KYOUNGSUN KIM, Suwon-si (KR); JONGHOON KIM, Suwon-si (KR); SUNGJOO PARK, Suwon-si (KR); HOYOUNG SONG, Suwon-si (KR); YOUNG-HO LEE, Suwon-si (KR)

(21) Appl. No.: 18/774,957

(22) Filed: Jul. 17, 2024

(30) Foreign Application Priority Data
Jan. 12, 2024 (KR) 10-2024-0005526

(51) Int. Cl. G06F 13/40; G06F 13/16

(52) U.S. Cl. CPC G06F 13/4022; G06F 13/1673

(57) ABSTRACT

A memory device according to an embodiment includes a memory cell array for storing data, data lines for transmitting the data, path changing switches connected to the data lines, and a controller for receiving a first selection signal and a second selection signal that are rank selecting signals from a memory controller. The controller controls opening/closing of the path changing switches based on the first selection signal and the second selection signal.

### CROSS-REFERENCE TO RELATED APPLICATION

This application claims priority to and the benefit of Korean Patent Application No. 10-2024-0005526 filed in the Korean Intellectual Property Office on Jan. 12, 2024, the entire contents of which are incorporated herein by reference.

### BACKGROUND

### (a) Field

The present invention relates to a memory device.

### (b) Description of the Related Art

To achieve high capacity and high performance of a memory system, the memory system is equipped with memory modules, and each memory module is equipped with memory chips. In the memory module, a set of memory chips that operate together as a group is generally referred to as a rank, and depending on the number of the ranks in the memory module, there are a 1-rank memory module and an N-rank memory module (here, N is a natural number of 2 or more). The 1-rank memory module refers to a memory module in which the entire memory chips in the memory module operate together, and the N-rank memory module refers to a memory module in which the memory chips in the memory module are divided into N groups and operate for respective groups.

### SUMMARY

An aspect of the present invention attempts to provide a memory device for increasing data input/output rates.

An embodiment of the present invention provides a memory device includes a memory cell array configured to store data, a plurality of data lines configured to transmit the data, path changing switches connected to the plurality of data lines, and a controller configured to receive a first selection signal and a second selection signal, which are rank selecting signals from a memory controller. The controller is configured to control opening/closing of the path changing switches based on the first selection signal and the second selection signal.

Another embodiment of the present invention provides a memory device includes a memory cell array configured to store data, a plurality of data pins configured to input/output the data. The plurality of data pins includes first data pins and second data pins. The memory device further includes first data lines connecting the first data pins and the memory cell array, second data lines connecting the second data pins and the memory cell array, and a first path changing switch connected to the first data lines and the second data lines and adjusting an input/output path of the data based on a first control signal.

Another embodiment of the present invention provides a memory device includes a plurality of memory chips configured to input/output data with a predetermined size and including path changing switches connected to data lines, a controller configured to determine a data input/output path in the plurality of memory chips by opening/closing the path changing switches based on a first rank selecting signal and a second rank selecting signal.

### BRIEF DESCRIPTION OF THE DRAWINGS

FIG. 1 shows a block diagram of a memory system according to an embodiment.

FIG. 2 shows a block diagram of a memory system according to an embodiment.

FIG. 3 shows a circuit diagram of a portion of a memory chip according to an embodiment.

FIG. 4 shows a circuit diagram of a controller according to an embodiment.

FIG. 5 shows a block diagram of a memory device according to an embodiment.

FIG. 6 shows an input/output path of a memory chip according to an embodiment.

FIG. 7 shows a block diagram of a memory device according to an embodiment.

FIG. 8 shows an input/output path of a memory chip according to an embodiment.

FIG. 9 shows a block diagram of a memory system according to an embodiment.

FIG. 10 shows a block diagram of a memory device according to an embodiment.

FIG. 11 shows an input/output path of memory chips according to an embodiment.

FIG. 12 shows an input/output path of memory chips according to an embodiment.

FIG. 13 shows a circuit diagram of a controller according to an embodiment.

FIG. 14 shows a block diagram of a memory device according to an embodiment.

FIG. 15 shows an input/output path of a memory chip according to an embodiment.

FIG. 16 shows an input/output path of a memory chip according to an embodiment.

FIG. 17 shows a circuit diagram of a portion of a memory chip according to an embodiment.

FIG. 18 shows a block diagram of a computing system to which a storage system is adapted according to an embodiment.

FIG. 19 shows a block diagram of a data center to which a computer system is adapted according to an embodiment.

### DETAILED DESCRIPTION OF THE EMBODIMENTS

In the following detailed description, only certain embodiments of the present invention have been shown and described, simply by way of illustration. As those skilled in the art would realize, the described embodiments may be modified in various different ways, all without departing from the spirit or scope of the present invention.

Accordingly, the drawings and description are to be regarded as illustrative in nature and not restrictive, and like reference numerals designate like elements throughout the specification. In the flowcharts described with reference to the drawings in this specification, the operation order may be changed, various operations may be merged, certain operations may be divided, and certain operations may not be performed.

An expression recited in the singular may be construed as singular or plural unless the expression “one”, “single”, etc., is used. Terms including ordinal numbers such as first, second, and the like, will be used only to describe various components, and are not to be interpreted as limiting these components. The terms may be only used to differentiate one component from others. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

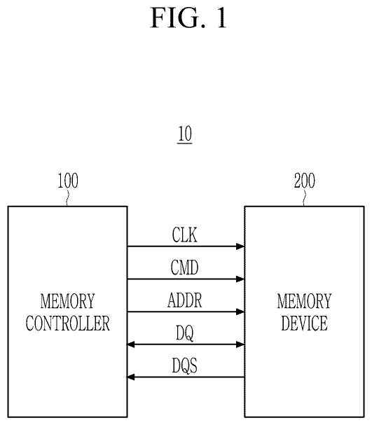

FIG. 1 shows a block diagram of a memory system according to an embodiment.

Referring to FIG. 1, the memory system 10 according to an embodiment may be disposed on an electronic device. For example, the electronic device may be realized with a personal computer (PC), laptop computer, a mobile phone, a smartphone, a tablet PC, a personal digital assistant (PDA), an enterprise digital assistant (EDA), a digital still camera, a digital video camera, a portable multimedia player (PMP), a personal navigation device or portable navigation device (PND), a handheld game console, a mobile Internet device (MID), a wearable computer, an Internet of things (IoT) device, an Internet of everything (IoE)) device, or a drone.

The memory system 10 may include a memory controller 100 and a memory device 200.

The memory controller 100 may control a general operation of the memory system 10. The memory controller 100 may write data DQ to the memory device 200 or may read the data DQ from the memory device 200 by using clock signals CLK, commands CMD, and addresses ADDR. For example, the memory controller 100 may control an operation of the memory device 200 by providing the command CMD and the address ADDR to the memory device 200 in synchronization with the clock signals CLK. The memory device 200 may transmit the data DQ and a data strobe signal DQS to the memory controller 100. For example, the memory controller 100 and the memory device 200 may be connected to each other by using individual pins and individual transmission lines to transmit/receive the clock signals CLK, the commands CMD, the addresses ADDR, the data DQ, or the data strobe signals DQS.

The memory controller 100 may communicate with the memory device 200 by using an interface protocol such as a compute express link (CXL), a peripheral component interconnect express (PCIe), an advanced technology attachment (ATA), a serial ATA (SATA), a parallel ATA (PATA), or a serial attached SCSI (SAS). The interface protocols between the memory controller 100 and the memory device 200 are not limited thereto, and may be one of other interface protocols such as a universal serial bus (USB), a multi-media card (MMC), an enhanced small disk interface (ESDI), or an integrated drive electronics (IDE).

The memory device 200 may write or output the data DQ at its storage area based on (or in response to) an instruction of the memory controller 100. The memory device 200 may be or include at least one set of a plurality of memory chips formed on a board. The set of the plurality of memory chips may be formed on a module board to be a memory module or may be formed on a system board such as a motherboard to be an on-board memory. The memory device 200 may therefore be a memory module or an on-board memory. For example, the memory device 200 may be a double data rate synchronous dynamic random access memory (DDR SDRAM), a low power DDR (LPDDR) SDRAM, a graphics DDR (GDDR) SDRAM, a Rambus DRAM (RDRAM), a hybrid memory cube (HMC), a dual in-line memory module (DIMM), a high bandwidth memory (HBM), an optane DIMM, and/or a nonvolatile DIMM (NVDIMM)

Depending on embodiments, the memory device 200 may be or include a one-rank memory or a multi-rank memory. When the memory device 200 includes the multi-rank memories, the memory controller 100 may communicate with a selected one of the ranks by transmitting a selection signal to the memory device 200.

The memory device 200 may include switches for changing data paths. The switches may be connected to data lines of the memory device 200. For example, the data lines may include first data lines connected to a memory cell array and first data pins (or pads) and second data lines connected to the memory cell array and second data pins. The memory device 200 may include first switches connected to the first data lines; second switches connected to the second data lines; and third switches connected to the first data lines and the second data lines.

The memory device 200 may change the data path by controlling opening/closing (i.e., opening and/or closing) of the switches. The memory device 200 may control the opening/closing of the switches so that data may be input/output through a specific data pin. Hence, when the memory device 200 is configured with multiple ranks, the memory controller 100 may be operated in a similar way to the one-rank memory and may achieve excellent signal integrity (SI).

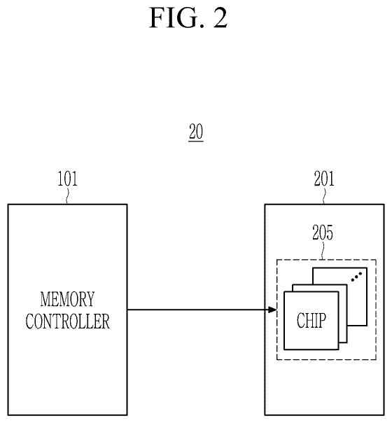

FIG. 2 shows a block diagram of a memory system according to an embodiment.

Referring to FIG. 2, the memory system 20 according to an embodiment may include a memory controller 101 and a memory device 201. The memory device 201 may be a memory module or an on-board memory. The memory device 201 may be or include at least one set of plurality of memory chips. The memory device 201 may include at least one memory module (or at least one on-board memory) 205. The memory controller 101 may write data to the memory device 201 or may read the data from the memory device 201. The description on the memory controller 100 of FIG. 1 may be applied to the memory controller 101. No repeated descriptions will be provided.

The memory device 201 may be or include a one-rank memory module 205. The one-rank memory module 205 may include memory chips that operate together as a group. The memory controller 101 may select the memory module 205 based on a second-level of a signal CS0 (also referred to as a second-level signal CS0), and may not select the memory module 205 based on a first-level of the signal CS0 (also referred to as a first-level signal CS0). As the memory device 201 is configured with one rank, the memory controller 101 may transmit the first-level of a signal CS1 to the memory module 205.

The memory module 205 may include semiconductor chips. The semiconductor chips may be memory chips. The respective memory chips included in the memory module 205 may input/output 2^{d}-bit data (here, d is an integer of 1 or more). For example, the respective memory chips may input or output data with a predetermined size such as 4 bits, 8 bits, or 16 bits. The memory module 205 may be referred to as 1R×4, 1R×8, or 1R×16. Here, 1R indicates that the memory module 205 is configured with one rank, and the number given after x indicates the predetermined size with which the respective memory chips may input or output data such as 4 bits, 8 bits, or 16 bits.

The respective memory chips may include the data pins with the number that is equal to or greater than the number indicating the predetermined size. For example, the respective memory chips may have four data pins, and may input/output 4-bit data. For example, the respective memory chips may include eight data pins, and may input/output 4-bit data. For example, the respective memory chips may include eight data pins, and may input/output 8-bit data.

The number of memory chips included in the memory module 205 may be determined based on a size of the data transmitted/received by the memory controller 101 and the memory module 205 and a size of the data output by each of the memory chips. For example, the sizes of the data transmitted/received by the memory controller 101 and the memory module 205 may be 64 bits. When the size of the data output by each of the memory chips is 4 bits, the number of the memory chips included by the memory module 205 may be 16. When the size of the data output by each of the memory chips is 8 bits, the number of the memory chips included by the memory module 205 may be 8. The memory module 205 may further include a chip for error correction codes (ECC) operation. For example, one of the memory chips may be for ECC. Depending on embodiments, the numbers of the memory chips for the ECC operation included by the memory module 205 may be different.

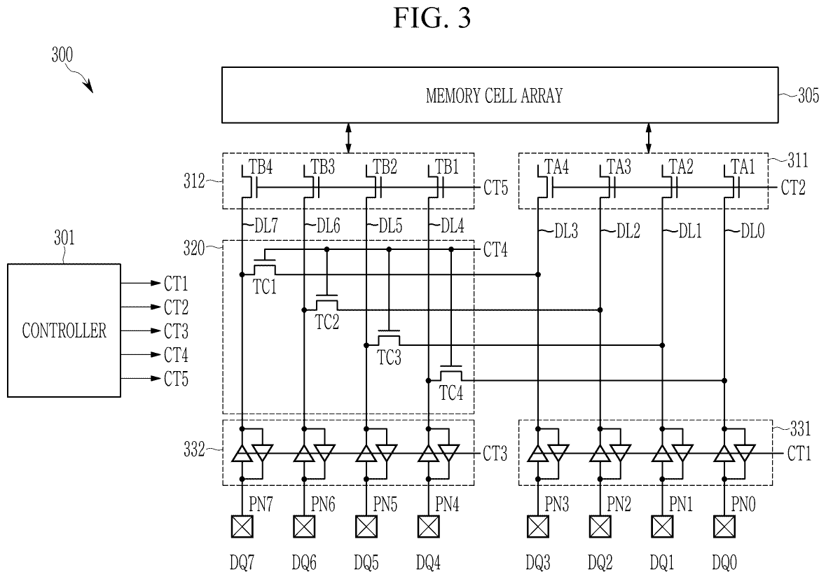

FIG. 3 shows a circuit diagram of a portion of a memory chip according to an embodiment.

Referring to FIG. 3, the memory chip 300 according to an embodiment may have eight data pins PN0 to PN7. For example, when the memory device including the memory chip 300 is 1R×4, the memory chip 300 may input/output 4-bit data DQ0 to DQ3 by using four data pins PN0 to PN3. In an embodiment, the memory chip 300 may use four data pins PN4 to PN7 to input/output 4-bit data. For another example, when the memory device including the memory chip 300 is 1R×8, the memory chip 300 may input/output 8-bit data DQ0 to DQ7 by using eight data pins PN0 to PN7. Depending on embodiments (e.g., a memory device including the memory chip 300 is 1R×16), the memory chip 300 may have additional data pins to input/output data of more than 8-bit.

The memory chip 300 may include a controller (also referred to as an “in-chip controller”) 301, a memory cell array 305, path changing switches 311, 312, and 320, and buffers 331 and 332.

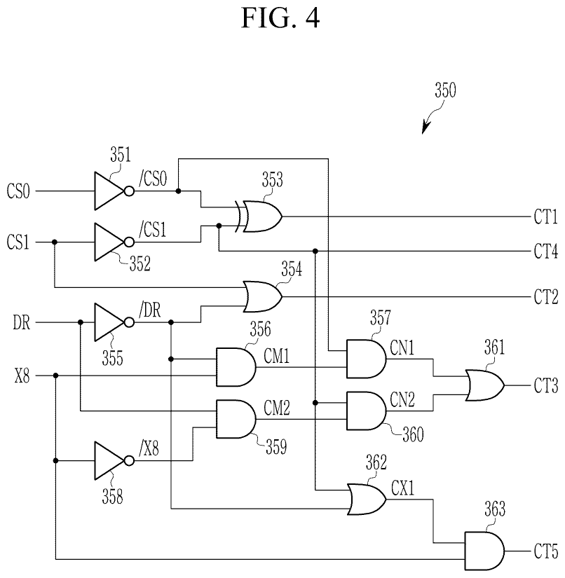

The controller 301 may generate control signals CT1 to CT5. The control signals CT1 and CT3 may control opening/closing of the buffers 331 and 332. Control signals CT2, CT4, and CT5 may control opening/closing of the path changing switches 311, 312, and 320. The controller 301 may generate control signals CT1 to CT5 based on the selection signal received from the memory controller. The configuration of the controller 301 to generate the control signals CT1 to CT5 will be described later with reference to FIG. 4. Depending on embodiments, the controller 301 may control a data read/write operation, a refresh operation, and a precharge operation of the memory cell array 305.

The memory cell array 305 may include memory cells, and may store data or may output the stored data based on the instruction from the memory controller. The memory cell array 305 may be operable based on the instruction of the controller 301.

The path changing switches 311, 312, and 320 may be opened/closed based on the control signals CT2, CT4, and CT5, and a transmission path of the data DQ0 to DQ7 may be changed according to the opening/closing of the path changing switches 311, 312, and 320.

The path changing switches 311, 312, and 320 may include transistors TA1 to TA4, TB1 to TB4, and TC1 to TC4. The transistors TA1 to TA4, TB1 to TB4, and TC1 to TC4 may be metal oxide silicon (or semiconductor) field effect transistors (MOSFET). Depending on embodiments, the transistors TA1 to TA4, TB1 to TB4, and TC1 to TC4 may be P-channel transistors or N-channel transistors.

The transistors TA1 to TA4, TB1 to TB4, and TC1 to TC4 may receive the control signals CT2, CT4, and CT5 through gates, and sources and drains may be connected to the data lines DL0 to DL7 and may transmit the data DQ0 to DQ7 based on the control signals CT2, CT4, and CT5.

The path changing switches 311 and 312 may transmit the data received from the memory cell array 305 to the data lines DL0 to DL7, or may transmit the data received from the data lines DL0 to DL7 to the memory cell array 305.

The path changing switch 311 may transmit data to the data lines DL0 to DL3 based on the first-level (e.g., high logic level) of the control signal CT2. The path changing switch 311 may not transmit data based on the second-level (e.g., low logic level) of the control signal CT2.

The path changing switch 312 may transmit data to data lines DL4 to DL7 based on the first-level of the control signal CT2. The path changing switch 312 may not transmit data based on the second-level of the control signal CT2.

The path changing switch 320 may connect the data lines DL0 to DL3 and the data lines DL4 to DL7. The path changing switch 320 may connect the path changing switch 311 and the path changing switch 312. The path changing switch 320 may transmit data in the data lines (e.g., DL4 to DL7) to the other data lines (e.g., DL0 to DL3), and vice versa.

The path changing switch 320 may transmit data of the data lines (e.g., DL4 to DL7) to the other data lines (e.g., DL0 to DL3) based on the first-level of the control signal CT4. The path changing switch 320 may not transmit data based on the second-level of the control signal CT4.

The buffers 331 and 332 may delay the data DQ0 to DQ7 based on the control signals CT1 and CT3. The buffers 331 and 332 may be connected to the path changing switches 311, 312, and 320, and may receive or output the data DQ0 to DQ7 through the data pins PN0 to PN7.

FIG. 4 shows a circuit diagram of a controller (also referred to as an “in-chip controller”) according to an embodiment.

Referring to FIG. 4, the controller 350 according to an embodiment may include logic circuits 351 to 363. The controller 350 may generate control signals CT1 to CT5 based on signals CS0, CS1, DR, and X8. The controller 350 may receive the signals CS0 and CS1 from the memory controller (e.g., 101 of FIG. 2). The memory controller may generate the signals CS0 and CS1 as chip selecting signals. The signals CS0 and CS1 may correspond to CS0_n and CS1_n defined by the Joint Electron Device Engineering Council (JEDEC) standard, and a second level (or low logic level) of the signals may indicates ‘On’ (i.e., a predetermined chip or set of chips may be selected).

The controller 350 may generate (or receive) the signals DR and X8. The signal DR indicates the number of ranks in the memory device. For example, the signal DR indicates whether the memory device (e.g., 201 of FIG. 2) is configured with a dual rank (or two ranks). The signal X8 indicates a number of external data bus interfaces (i.e., channels). Thus, the signal X8 may indicate a data size that can be transferred in a single operation by each of the memory chips of the memory device. For example, the signal X8 indicates whether a data size output by each of the memory chips of the memory device is 8 bits. The “signal X8” is also referred to simply as “size of input/output data.”

In an embodiment, the controller 350 may generate (or receive) signals DR and X8 based on (or from) a memory information stored in the memory device. For example, the memory device may include a read only memory (ROM) storing memory information. The memory information may include serial presence detect (SPD) information. The SPD information may include information on a number of ranks in the memory device, and may include a size of input/output data. For example, the controller 350 may determine (or recognize) a type of the memory device, e.g., 1R×4, 1R×8, 1R×16, 2R×4, and 2R×8, based on the SPD information.

The controller 350 may generate a signal X8 based on the type of the memory device. For example, the controller 350 may generate a first-level of the signal X8 when each of the memory chips inputs/outputs 8-bit data. The controller 350 may generate a second-level of the signal X8 when each of the memory chips inputs/outputs 4-bit data.

The controller 350 may generate a signal DR based on the type of the memory device. For example, the controller 350 may generate a first-level of the signal DR when the memory device is configured with two ranks. The controller 350 may generate a second-level of the signal DR when the memory device is configured with one rank.

In an embodiment, the controller 350 may generate a signal DR based on the signals CS0 and CS1. The controller 350 may generate a first-level of the signal DR when detecting changes of levels of the signals CS0 and CS1. For example, the controller 350 may generate a first-level of the signal DR when detecting that the signal CS1 changes to the second level from the first level. Depending on embodiments, the controller 350 may detect the change of the level of the signal CS0 and may generate a signal DR when the signal CS0 and the signal CS1 are changed and input.

The logic circuits 351 to 363 may generate control signals CT1 to CT5 based on the signals CS0, CS1, DR, and X8. The logic circuits 351 to 363 may include inverters 351, 352, 355, and 358, an XOR gate 353, OR gates 354, 361, and 362, and AND gates 356, 357, 359, 360, and 363. For example, the logic circuits 351, 352, 355, and 358 may be inverters. The logic circuit 353 may be an XOR gate. The logic circuits 354, 361, and 362 may be OR gates. The logic circuits 356, 357, 359, 360, and 363 may be AND gates. The signals CS0, CS1, DR, and X8 may be input to the inverters 351, 352, 355, and 358, the OR gate 354, and the AND gate 356, 359, and 363.

The inverter 351 may invert the signal CS0 and may output a signal /CS0. The signal /CS0 may be input to the XOR gate 353. The inverter 352 may invert the signal CS1 and may output a signal /CS1. The signal /CS1 may be input to the XOR gate 353. The XOR gate 353 may perform an XOR operation on the signals /CS0 and /CS1 to generate a control signal CT1. The signal /CS0 may also be input to the AND gate 357. The signal /CS1 may be input to the AND gate 360 and the OR gate 362. The signal /CS1 may be used as a control signal CT4.

The inverter 355 may invert the signal DR and may output a signal /DR. The OR gate 354 may perform an OR operation on the signals CS1 and /DR to generate a control signal CT2. The signal /DR may be input to the AND gate 356 and the OR gate 362.

The AND gate 356 may perform an AND operation on the signals /DR and X8 to generate a signal CM1. The AND gate 356 may output the signal CM1 to the AND gate 357. The AND gate 357 may perform an AND operation on the signals /CS0 and CM1 to generate a signal CN1. The AND gate 357 may output the signal CN1 to the OR gate 361.

The inverter 358 may invert the signal X8 and may output a signal /X8. The AND gate 359 may perform an AND operation on the signals DR and /X8 to generate a signal CM2. The AND gate 359 may output the signal CM2 to the AND gate 360. The AND gate 360 may perform an AND operation on the signals /CS1 and CM2 to generate a signal CN2. The AND gate 360 may output the signal CN2 to the OR gate 361. The OR gate 361 may perform an OR operation on the signals CN1 and CN2 to generate a control signal CT3.

The OR gate 362 may perform an OR operation on the signals /CS1 and /DR to generate a signal CX1. The OR gate 362 may output the signal CX1 to the AND gate 363. The AND gate 363 may perform an AND operation on the signals CX1 and X8 to generate a control signal CT5.

The controller 350 may generate control signals CT1 to CT5 based on Equation 1.

$$CT 1 = - CS 0 \hat{} - CS 1 \\ CT 2 = - DR ‖ CS 1 \\ CT 3 = ( - DR \&\& X 8 \&\& - CS 0 ) ‖ ( DR \&\& - X 8 \&\& - CS 1 ) \\ CT 4 = - CS 1 \\ CT 5 = X 8 \&\& ( - DR ‖ - CS 1 ) \qquad ( Equation 1 )$$

Here, CT1, CT2, CT3, CT4, and CT5 represent the control signals CT1 to CT5. CS0, CS1, DR, X8 represent the signals CS0, CS1, DR, and X8. ‘-’ represents an inverting operation. ‘\hat{ }’ represents an XOR operation. ‘∥’ represents an OR operation. ‘&&’ represents an AND operation. The control signals CT1 to CT5 may be used to change input/output paths of data in the memory chip (e.g., 300 of FIG. 3).

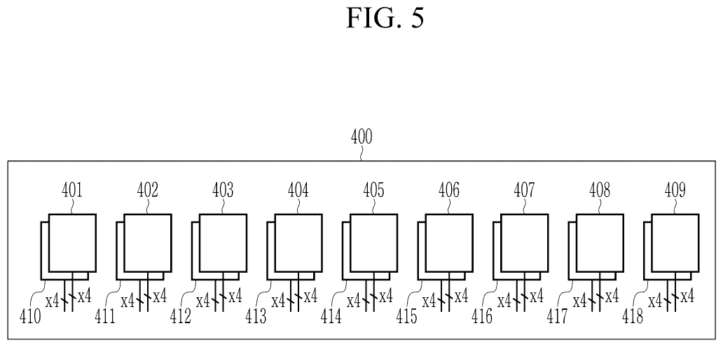

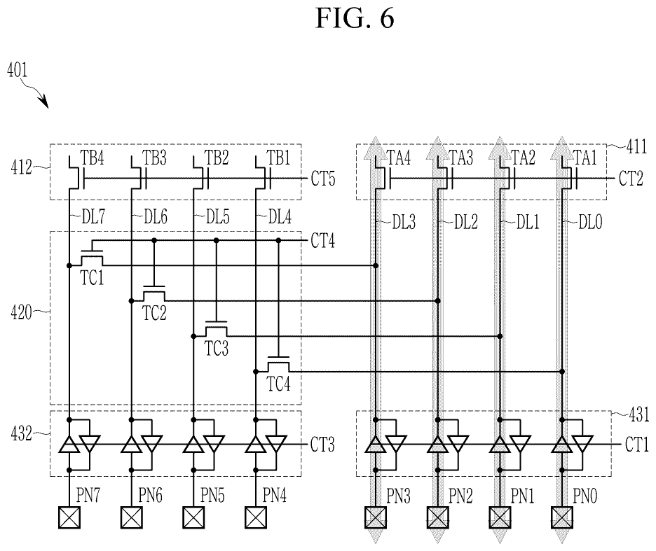

FIG. 5 shows a block diagram of a memory device according to an embodiment, and FIG. 6 shows an input/output path of a memory chip according to an embodiment.

Referring to FIG. 5, the memory device 400 may be the 1R×4 type. The memory device 400 may include memory chips 401 to 418 for inputting/outputting 4-bit data. In an embodiment, a set of the memory chips 401 to 408 and 410 to 417 may input/output 64-bit data, and the memory chips 409 and 418 may perform an ECC operation. Depending on embodiments, the number of the memory chips performing an ECC operation may be two or more.

Referring to FIG. 3, FIG. 4, and FIG. 6, the controller 301 may receive a second-level signal CS0 and a first-level signal CS1. The controller 301 may generate signals DR and X8 based on the memory information or the signals CS0 and CS1. The controller 301 may generate second-levels of the signals (also referred to as “second-level the signals”) DR and X8. The controller 301 may generate a first-level control signal CT1, a first-level control signal CT2, a second-level control signal CT3, a second-level control signal CT4, and a second-level control signal CT5 based on the signals CS0, CS1, DR, and X8. The first level may represent a high logic level and the second level represent a low logic level, and the embodiment is not limited thereto. The description given with FIG. 3 and FIG. 4 may be applied to the control signals CT1 to CT5. No repeated descriptions will be provided.

The memory chip 401 may include path changing switches 411, 412, and 420 and buffers 431 and 432. The memory chip 401 may further include a controller (also referred to as an “in-chip controller”), a memory cell array, etc. The memory chip 401 may input/output data based on the control signals CT1 to CT5.

The buffer 431 may be operable based on the first-level control signal CT1. The buffer 431 may delay input/output data. The path changing switch 411 may be closed based on the first-level control signal CT2, and may pass through the input/output data.

The path changing switches 412 and 420 may be opened based on the second-level control signals CT4 and CT5. The buffer 432 may receive the second-level control signal CT3 and may not be operated. Hence, the memory chip 401 may input/output 4-bit data through the data lines DL0 to DL3.

FIG. 6 shows that the data are input/output through the data lines DL0 to DL3, to which the embodiments are not limited, and the memory chip 401 may input/output data through the data lines DL4 to DL7.

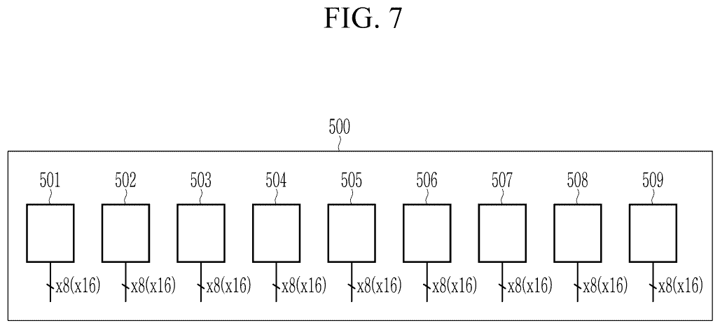

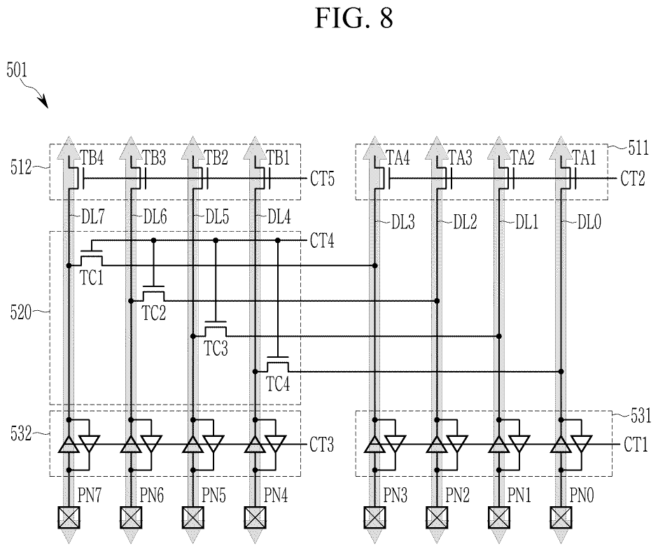

FIG. 7 shows a block diagram of a memory device according to an embodiment, and FIG. 8 shows an input/output path of a memory chip according to an embodiment.

Referring to FIG. 7, the memory device 500 may be the 1R×8 type. The memory device 500 may include memory chips 501 to 509 for inputting/outputting 8-bit data. In an embodiment, the memory chips 501 to 508 may input/output 64-bit data, and the memory chip 509 may perform an ECC operation. Depending on embodiments, the number of the memory chips performing an ECC operation may be two or more.

In an embodiment, the memory device 500 is the 1R×16 type, and the memory device 500 may include the memory chips 501 to 509 for inputting/outputting 16-bit data. In this case, the memory chips 501 to 509 may have 16 data pins. The memory chips 501 to 509 may respectively include one set of path changing switches 311, 312, and 320 and two sets of buffers 331 and 332 shown in FIG. 3, and may connect the memory cell array 305 and the sixteen data pins by using two sets of the path changing switches and buffers. For example, the memory chips 501 to 509 each may include two sets of path changing switches and buffers, thereby the memory cell array 305 and the sixteen data pins may be connected. Each set of the two sets of the path changing switches and buffers corresponds to the path changing switches 311, 312, and 320 and buffers 331 and 332 shown in FIG. 3.

Referring to FIG. 3, FIG. 4, and FIG. 8, the controller 301 may receive the second-level signal CS0 and the first-level signal CS1. The controller 301 may generate signals DR and X8 based on the memory information or the signals CS0 and CS1. The controller 301 may generate a first-level signal X8 and a second-level signal DR. The controller 301 may generate a first-level control signal CT1, a first-level control signal CT2, a first-level control signal CT3, a second-level control signal CT4, and a first-level control signal CT5 based on the signals CS0, CS1, DR, and X8. The first level represents a high logic level and the second level represents a low logic level, and the embodiment is not limited thereto. The description given with FIG. 3 and FIG. 4 may be applied to the control signals CT1 to CT5. No repeated descriptions will be provided.

The memory chip 501 may include path changing switches 511, 512, and 520, and buffers 531 and 532. The memory chip 501 may further include a controller (also referred to as an “in-chip controller”), a memory cell array, etc. The memory chip 501 may input/output data based on control signals CT1 to CT5.

The buffers 531 and 532 may be operated based on the first-level control signals CT1 and CT3. The buffers 531 and 532 may delay input/output data. The path changing switches 511 and 512 may be closed and may pass the input/output data based on the first-level control signals CT2 and CT5.

The path changing switch 520 may be opened based on the second-level control signal CT4. Hence, the memory chip 501 may input/output 8-bit data through the data lines DL0 to DL7.

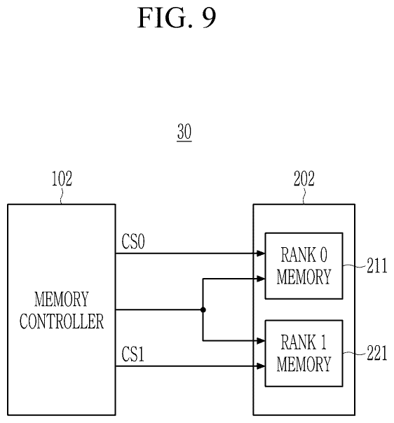

FIG. 9 shows a block diagram of a memory system according to an embodiment.

Referring to FIG. 9, the memory system 30 according to an embodiment may include a memory controller 102 and a memory device 202. The memory controller 102 may write data to the memory device 202 or may read the data from the memory device 202. The description on the memory controller 100 of FIG. 1 may be applied to the memory controller 102. No repeated descriptions will be provided.

The memory device 202 may be or include at least one set of plurality of memory chips. The memory device 202 may include at least one memory module (or an on-board memory) 205. For example, the memory device 202 may include a memory module 211 and a memory module 212. The memory controller 102 may select the memory modules 211 and 212 based on the second-level signals CS0 and CS1, and may not select the memory modules 211 and 212 based on the first-level signals CS0 and CS1.

The memory modules 211 and 212 may include memory chips. The respective memory chips included in the memory modules 211 and 212 may input/output 2^{d}-bit data (d is an integer of 1 or more). For example, the respective memory chips may input/output data with a predetermined size such as 4 bits, 8 bits, or 16 bits.

The respective memory chips may include data pins with the number that is equal to or greater than a predetermined size. For example, the respective memory chips may include four data pins, and may input/output 4-bit data. For example, the respective memory chips may include eight data pins, and may input/output 4-bit data. For example, the respective memory chips may include eight data pins, and may input/output 8-bit data.

The number of the memory chips included by the memory modules 211 and 212 may be determined based on the size of the data transmitted/received by the memory controller 102 and the memory modules 211 and 212, and based on the size of the data output by each of memory chips. For example, the size of the data transmitted/received by the memory controller 102 and each of the memory modules 211 and 212 may be 64 bits. When the size of the data output by each of memory chips is 4 bits, the number of the memory chips included by each of the memory modules 211 and 212 may be 16. When the size of the data output by each of memory chips is 8 bits, the number of the memory chips included by each of the memory modules 211 and 212 may be 8. The memory modules 211 and 212 may include a chip for error correction codes (ECC) operation. For example, one of the memory chips may be for ECC operation. Depending on embodiments, the number of the memory chip for the ECC operation included by the memory modules 211 and 212 may be different.

In an embodiment, the memory device 202 may include a first set of plurality of memory chips 211. The first set of plurality of memory chips 211 may be a first rank RANK0. The memory device 202 may include a second set of plurality of memory chips 221. The second set of plurality of memory chips 221 may be a second rank RANK1. The memory controller 102 may select the ranks 211 and 212 based on the second-level signals CS0 and CS1, and may not select the ranks 211 and 212 based on the first-level signals CS0 and CS1. The memory device 202 may be expressed as 2R×4 or 2R×8 according to the sizes of the data input/output by the respective memory chips. In this instance, 2R indicates that the memory device 202 is configured with two ranks RANK0 and RANK1, and the number after x indicates a predetermined size.

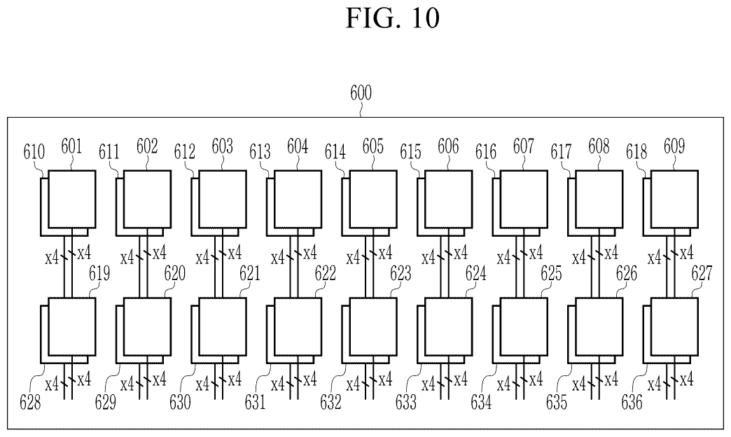

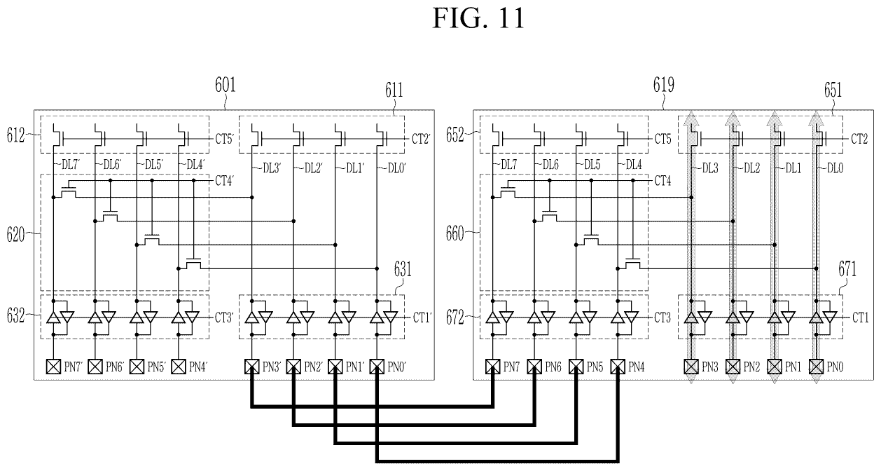

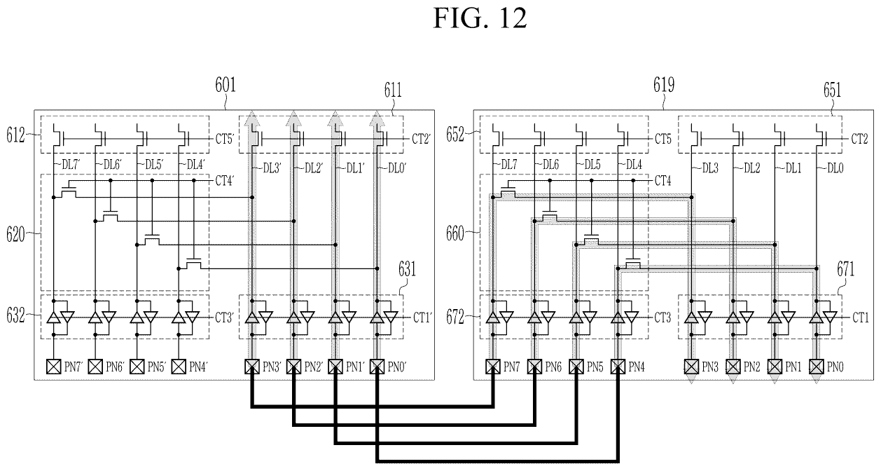

FIG. 10 shows a block diagram of a memory device according to an embodiment, and FIG. 11 and FIG. 12 show an input/output path of memory chips according to an embodiment.

Referring to FIG. 10, the memory device 600 may be the 2R×4 type. The memory device 600 may include a first rank RANK0 (also referred to as a memory of RANK0) and a second rank RANK1 (also referred to as a memory of RANK2). The memory device 600 may input/output 64-bit data based on the selection signal CS0 of the memory of RANK0 or the selection signal CS1 of the memory of RANK1. The memory device 600 may include memory chips 601 to 636 for inputting/outputting 4-bit data based on the selection signals (i.e., CS0 or CS1). In an embodiment, the memory chips 601 to 617 and 619 to 635 may input/output 64-bit data. In an embodiment, a first set (or a first module) of the memory chips 601 to 617 635 may input/output 64-bit data, and a second set (or a second module) of the memory chips 619 to 635 may input/output 64-bit data. The memory chips 609, 618, 627, and 636 may perform an ECC operation. Depending on embodiments, the number of the memory chips performing an ECC operation may be equal to or greater than 8.

Referring to FIG. 3, FIG. 4, and FIG. 11, the controller 301 may receive the second-level signal CS0 and the first-level signal CS1. For example, the memory controller 102 of FIG. 9 may transmit a signal (i.e., a set of signals CS0 and CS1) for selecting the memory of RANK0 (including a memory chip 601) and not selecting the memory of RANK1 to the memory device. The controller 301 may generate signals DR and X8 based on the memory information or the signals CS0 and CS1. The controller 301 may generate a first-level signal DR and a second-level signal X8. The controller 301 may generate a first-level control signal CT1, a first-level control signal CT2, a second-level control signal CT3, a second-level control signal CT4, and a second-level control signal CT5 based on the signals CS0, CS1, DR, and X8. The description given with FIG. 3 and FIG. 4 may be applied to the control signals CT1 to CT5. No repeated descriptions will be provided.

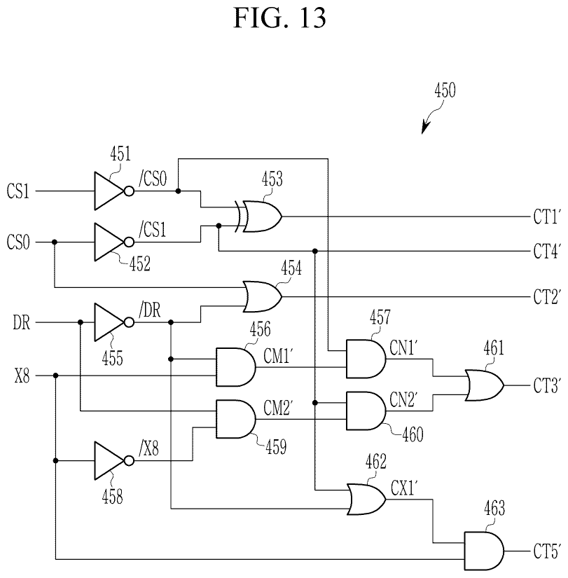

The controller 301 may generate control signals CT1′ to CT5′ based on the signals CS0, CS1, DR, and X8. The controller 301 may generate a first-level control signal CT1′, a second-level control signal CT2′, a first-level control signal CT3′, a first-level control signal CT4′, and a second-level control signal CT5′. A configuration for the controller 301 to generate control signals CT1′ to CT5′ will be described later with reference to FIG. 13. The first level represents a high logic level and the second level represents a low logic level, and the embodiment is not limited thereto.

The memory chips 601 and 619 may include the same configuration as the memory chip 300 of FIG. 3. The memory chip 601 may be connected to the memory chip 619. For example, data pins PN0′ to PN3′ of the memory chip 601 may be connected to the data pins PN4 to PN7 of the memory chip 619. Hence, the data of the memory chip 601 may be input/output through the memory chip 619.

The memory chips 601 and 619 may include path changing switches 611, 612, 620, 651, 652, and 660, and buffers 631, 632, 671, and 672. The memory chips 601 and 619 may further include a controller (also referred to as an “in-chip controller”), a memory cell array, etc. The memory chip 601 may be operated based on the control signals CT1′ to CT5′, and the memory chip 619 may be operated based on the control signals CT1 to CT5. Referring to FIG. 10, the memory chips 601 to 618 in an upper row may be operated based on the control signals CT1′ to CT5′, and the memory chips 619 to 636 may be operated based on the control signals CT1 to CT5. In an embodiment, the set of the memory chips 601 to 618 in an upper row may be a first rank, the set of the memory chips 610 to 636 in a lower row may be a second rank.

In an embodiment, the memory chip 601 may not be operable by the first-level signal CS1. In an embodiment, the memory chip 601 may not be operable by the second-level signal CS0. Hence, the memory chip 601 may not input/output data when receiving the first-level control signal CT1′, the second-level control signal CT2′, the first-level control signal CT3′, the first-level control signal CT4′, and the second-level control signal CT5′.

In the memory chip 619, the buffer 671 may be operated based on the first-level control signal CT1. The buffer 671 may delay the input/output data. The path changing switch 651 may be closed based on the first-level control signal CT2, and may allow the input/output data to pass through.

The path changing switches 652 and 660 may be opened based on the second-level control signals CT4 and CT5. The buffer 672 may receive the second-level control signal CT3 and may not be operated. Hence, the memory chip 619 may input/output 4-bit data through the data lines DL0 to DL3.

Referring to FIG. 3, FIG. 4, and FIG. 12, the controller 301 may receive the first-level signal CS0 and the second-level signal CS1. For example, the memory controller 102 of FIG. 9 may transmit a signal for selecting the memory of RANK1 and not selecting the memory of RANK0 to the memory device (including the memory chip 601). The controller 301 may generate signals DR and X8 based on the memory information or the signals CS0 and CS1. The controller 301 may generate a first-level signal DR and a second-level signal X8. The controller 301 may generate a first-level control signal CT1, a second-level control signal CT2, a first-level control signal CT3, a first-level control signal CT4, and a second-level control signal CT5 based on the signals CS0, CS1, DR, and X8. The description given with FIG. 3 and FIG. 4 may be applied to the control signals CT1 to CT5. No repeated descriptions will be provided.

The controller 301 may generate control signals CT1′ to CT5′ based on the signals CS0, CS1, DR, and X8. The controller 301 may generate a first-level control signal CT1′, a first-level control signal CT2′, a second-level control signal CT3′, a second-level control signal CT4′, and a second-level control signal CT5′. A configuration for the controller 301 to generate control signals CT1′ to CT5′ will be described later with reference to FIG. 13. The first level represents a high logic level and the second level represents a low logic level, and the embodiment is not limited thereto.

In the memory chip 601, the buffer 631 may be operated based on the first-level control signal CT1′. The buffer 631 may delay the input/output data. The path changing switch 611 may be closed based on the first-level control signal CT2′, and may allow the input/output data to pass through.

The path changing switches 612 and 620 may be opened based on the second-level control signals CT4′ and CT5′. The buffer 632 may receive the second-level control signal CT3′ and may not be operated. Hence, the memory chip 601 may input/output 4-bit data through the data lines DL0′ to DL3′.

In the memory chip 619, the buffers 671 and 672 may be operated based on the first-level control signals CT1 and CT3. The buffers 671 and 672 may delay the input/output data. The path changing switch 660 may be closed based on the first-level control signal CT4, and may allow the input/output data to pass through. The path changing switches 651 and 652 may be opened based on the second-level control signals CT2 and CT5. Hence, the memory chip 619 may input/output 4-bit data through the data lines DL0 to DL7.

FIG. 13 shows a circuit diagram of a controller (also referred to as an “in-chip controller”) according to an embodiment.

Referring to FIG. 13, the controller 450 may include logic circuits 451 to 463. The controller 450 may generate control signals CT1′ to CT5′ based on the signals CS0, CS1, DR, and X8. The controller 450 may receive the signals CS0 and CS1 from the memory controller (e.g., 102 of FIG. 9). The memory controller may generate the signals CS0 and CS1 as chip selecting signals. The signals CS0 and CS1 may correspond to the CS0_n and CS1_n defined by the JEDEC standard, and the second level (low) may indicate On.

The controller 450 may generate signals DR and X8. The signal DR indicates whether the memory device (e.g., 600 of FIG. 10) has a dual rank (two ranks), and the signal X8 indicates whether the size of the data output by one memory chip of the memory device is 8 bits.

In an embodiment, the controller 450 may generate signals DR and X8 based on the memory information stored in the memory device. For example, the memory device may include a ROM for storing memory information. The memory information may include SPD information. The SPD information may include the rank of the memory device and the size of the input/output data. For example, the controller 450 may determine a type of the memory device, e.g., 1R×4, 1R×8, 1R×16, 2R×4, and 2R×8 based on the SPD information.

The controller 450 may generate a signal X8 based on the type of the memory device. For example, the controller 450 may generate a first-level signal X8 when each of the memory chips inputs/outputs 8-bit data. The controller 450 may generate a second-level signal X8 when each of the memory chips inputs/outputs 4-bit data.

The controller 450 may generate a signal DR based on the type of the memory device. For example, the controller 450 may generate a first-level signal DR when the memory device has two ranks. The controller 450 may generate a second-level signal DR when the memory device has one rank.

In an embodiment, the controller 450 may generate a signal DR based on the signals CS0 and CS1. The controller 450 may generate a first-level signal DR when detecting a change of levels of the signals CS0 and CS1. For example, the controller 450 may generate a first-level signal DR when detecting that the signal CS1 is changed to the second level from the first level. Depending on embodiments, the controller 450 may detect a level change of the signal CS0 and may generate a signal DR when the signal CS0 and the signal CS1 are changed between each other and are input.

The logic circuits 451 to 463 may generate control signals CT1′ to CT5′ based on the signals CS0, CS1, DR, and X8. The logic circuits 451 to 463 may include inverters 451, 452, 455, and 458, an XOR gate 453, OR gates 454, 461, and 462, and AND gates 456, 457, 459, 460, and 463. For example, the logic circuits 451, 452, 455, and 458 may be inverters. The logic circuit 453 may be an XOR gate. The logic circuits 454, 461, and 462 may be OR gates. The logic circuits 456, 457, 459, 460, and 463 may be AND gates. The signals CS0, CS1, DR, and X8 may be input to the inverters 451, 452, 455, and 458, the OR gate 454, and the AND gate 456, 459, and 463.

The inverter 451 may invert the signal CS1 and may output a signal /CS1. The signal /CS1 may be input to the XOR gate 453. The inverter 452 may invert the signal CS0 and may output a signal /CS0. The signal /CS0 may be input to the XOR gate 453. The XOR gate 453 may perform an XOR operation on the signals /CS0 and /CS1 to generate a control signal CT1′. The signal /CS1 may be input to the AND gate 457. The signal /CS0 may be input to the AND gate 460 and the OR gate 462. The signal /CS0 may be used as the control signal CT4′.

The inverter 455 may invert the signal DR and may output a signal /DR. The OR gate 454 may perform an OR operation on the signals CS0 and /DR to generate a control signal CT2′. The signal /DR may be input to the AND gate 456 and the OR gate 462.

The AND gate 456 may perform an AND operation on the signals /DR and X8 to generate a signal CM1′. The AND gate 456 may output the signal CM1′ to the AND gate 457. The AND gate 457 may perform an AND operation on the signals /CS1 and CM1′ to generate a signal CN1′. The AND gate 457 may output the signal CN1′ to the OR gate 461.

The inverter 458 may invert the signal X8 and may output a signal /X8. The AND gate 459 may perform an AND operation on the signals DR and /X8 to generate a signal CM2′. The AND gate 459 may output the signal CM2′ to the AND gate 460. The AND gate 460 may perform an AND operation on the signals /CS0 and CM2′ to generate a signal CN2′. The AND gate 460 may output the signal CN2′ to the OR gate 461. The OR gate 461 may perform an OR operation on the signals CN1′ and CN2′ to generate a control signal CT3′.

The OR gate 462 may perform an OR operation on the signals /CS0 and /DR to generate a signal CX1′. The OR gate 462 may output the signal CX1′ to the AND gate 463. The AND gate 463 may perform an AND operation on the signals CX1′ and X8 to generate a control signal CT5′.

The controller 450 may generate control signals CT1′ to CT5′ according to Equation 2.

$$CT {1}^{′} = - CS 0 \hat{} - CS 1 \\ CT {2}^{′} = - DR ‖ CS 0 \\ CT {3}^{′} = ( - DR \&\& X 8 \&\& - CS 1 ) ‖ ( DR \&\& - X 8 \&\& - CS 0 ) \\ CT {4}^{′} = - CS 0 \\ CT {5}^{′} = X 8 \&\& ( - DR ‖ - CS 0 ) \qquad ( Equation 2 )$$

Here, CT1′, CT2′, CT3′, CT4′, and CT5′ are the control signals CT1′ to CT5′. CS0, CS1, DR, and X8 represent the signals CS0, CS1, DR, and X8. ‘-’ represents the inverting operation. ‘\hat{ }’ represents the XOR operation. ‘∥’ represents the OR operation. ‘&&’ represents the AND operation. The control signals CT1′ to CT5′ may be used to change the input/output paths of data in the memory chip (e.g., 601 to 618 of FIG. 10).

In an embodiment of the invention, the memory system 30 of FIG. 9 may have a plurality of memory devices 202. The memory controller 102 may be connected to the plurality of memory devices 202 by a plurality of channels. Each channel may represent an independent communication path through which data travels between the memory controller 102 and the memory devices 202. For example, each of the channels may include a set of individual transmission lines to transmit/receive the clock signal CLK, the command CMD, the address ADDR, the data DQ, or the data strobe signal DQS, which are described in connection with FIG. 1. The memory controller 102 may write (or read) data to (or from) each of the memory devices 202 by using a corresponding one of the channels. Each of the memory devices 202 may be a memory module or an on-board memory. Each of the memory devices 202 may have a first rank and a second rank. Each of the memory chips of the first ranks of the plurality of the memory devices 202 may have a data path such as described in FIG. 11. Each of the memory chips of the second rank of the plurality of the memory devices 202 may have a data path such as described in FIG. 12. Each of the memory chips of the plurality of the memory devices 202 may have buffers corresponding to buffers 800 and 801 described below.

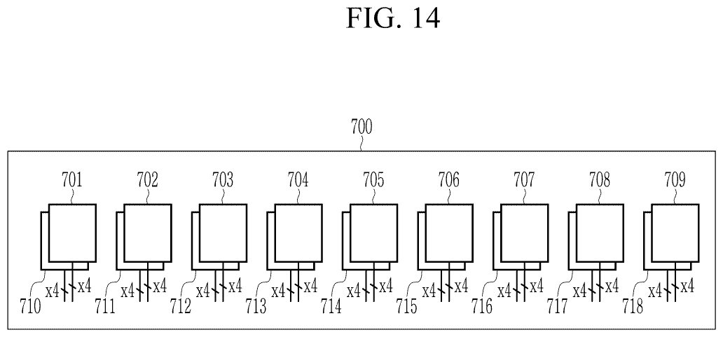

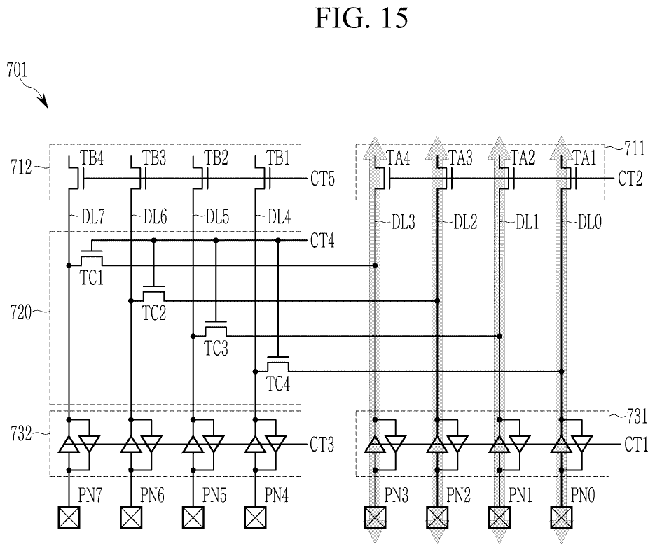

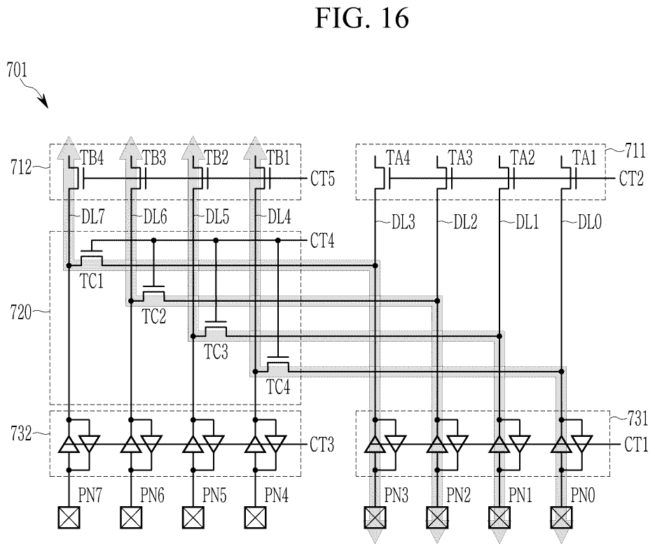

FIG. 14 shows a block diagram of a memory device according to an embodiment, and FIG. 15 and FIG. 16 show an input/output path of a memory chip according to an embodiment.

Referring to FIG. 14, the memory device 700 may be the 2R×8 type. The memory device 700 may include a memory of RANK0 and a memory of RANK1. The memory device 700 may input/output 64-bit data based on the selection signal CS0 of the memory of RANK0 or the selection signal CS1 of the memory of RANK1. The memory device 700 may include memory chips 701 to 718 for inputting/outputting 4-bit data based on the selection signal (i.e., CS0 or CS1). In an embodiment, the memory chips 701 to 708 and 710 to 717 may input/output 64-bit data. In an embodiment, a first set of the memory chips 701 to 717 735 may input/output 64-bit data, and a second set of the memory chips 719 to 735 may input/output 64-bit data. The memory chips 709 and 718 may perform the ECC operation. Depending on embodiments, the number of the memory chips performing an ECC operation may be two or more.

Referring to FIG. 3, FIG. 4, and FIG. 15, the controller 301 may receive the second-level signal CS0 and the first-level signal CS1. For example, the memory controller 102 of FIG. 9 may transmit a signal (i.e., a set of signals CS0 and CS1) for selecting the memory of RANK0 (including the memory chip 701) and not selecting the memory of RANK1 to the memory device. The controller 301 may generate signals DR and X8 based on the memory information or the signals CS0 and CS1. The controller 301 may generate first-level signals DR and X8. The controller 301 may generate a first-level control signal CT1, a first-level control signal CT2, a second-level control signal CT3, a second-level control signal CT4, and a second-level control signal CT5 based on the signals CS0, CS1, DR, and X8. The first level represents a high logic level and the second level represents a low logic level, and the embodiment is not limited thereto. The description given with FIG. 3 and FIG. 4 may be applied to the control signals CT1 to CT5. No repeated descriptions will be provided.

The memory chip 701 may include path changing switches 711, 712, and 720, and buffers 731 and 732. The memory chip 701 may further include a controller (also referred to as an “in-chip controller”), a memory cell array, etc. The memory chip 701 may input/output data based on the control signals CT1 to CT5.

The buffer 731 may be operated based on the first-level control signal CT1. The buffer 731 may delay the input/output data. The path changing switch 711 may be closed based on the first-level control signal CT2, and may allow the input/output data to pass through.

The path changing switches 712 and 720 may be opened based on the second-level control signals CT4 and CT5. The buffer 732 may receive the second-level control signal CT3 and may not be operated. Hence, the memory chip 701 may input/output 4-bit data through the data lines DL0 to DL3.

FIG. 15 shows the configuration of inputting/outputting data through the data lines DL0 to DL3, to which the embodiment is not limited, and the memory chip 701 may input/output data through the data lines DL4 to DL7.

Referring to FIG. 3, FIG. 4, and FIG. 16, the controller 301 may receive the first-level signal CS0 and the second-level signal CS1. For example, the memory controller 102 of FIG. 9 may transmit a signal (i.e., a set of signals CS0 and CS1) for selecting the memory of RANK1 and not selecting the memory of RANK0 to the memory device (including the memory chip 701). The controller 301 may generate signals DR and X8 based on the memory information or the signals CS0 and CS1. The controller 301 may generate first-level signals DR and X8. The controller 301 may generate a first-level control signal CT1, a second-level control signal CT2, a second-level control signal CT3, a first-level control signal CT4, and a first-level control signal CT5 based on the signals CS0, CS1, DR, and X8.

The buffer 731 may be operated based on the first-level control signal CT1. The buffer 731 may delay the input/output data. The path changing switch 711 may be opened based on the second-level control signal CT2. The path changing switches 712 and 720 may be closed based on the first-level control signals CT4 and CT5, and may allow the input/output data to pass through. The buffer 732 may receive the second-level control signal CT3 and may not be operated. Hence, the memory chip 701 may input/output 4-bit data through the data lines DL0 to DL3 on the data pin side and the data lines DL4 to DL7 on the memory cell array side. The embodiment is not limited thereto, and the memory chip 701 may input/output 4-bit data through the data lines DL4 to DL7 on the data pin side and the data lines DL0 to DL3 on the memory cell array side.

The description on the memory chip 701 of FIG. 15 and FIG. 16 may be applied to the memory chips 702 to 718 of FIG. 14. Hence, the memory device 700 of FIG. 14 may input/output 64-bit data by using different paths when the memory of RANK0 is selected (e.g., the second-level signal CS0 is received) or the memory of RANK1 is selected (e.g., the second-level signal CS1 is received).

In an embodiment of the invention, a memory device may include a plurality of memory chips corresponding to one or more of configurations of the memory chips described in connection with FIG. 1 to FIG. 16. For example, a memory device may include a plurality of memory chips having their data paths corresponding to one or more of data paths of the memory chips described with FIG. 1 to FIG. 16.

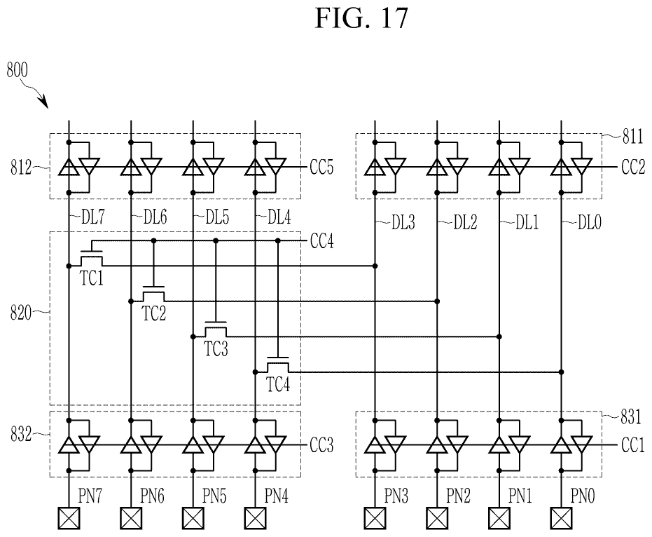

FIG. 17 shows a circuit diagram of a portion of a memory chip according to an embodiment.

Referring to FIG. 17, a memory device having a dual rank configuration (e.g., 202 in FIG. 9) may be provided. A data input/output timing of RANK0 may be different from a data input/output timing of RANK1. The data input/output timing (also referred to as “data input/output latency”) may be a response time of the memory device (or the memory chips) to a request by the memory controller. For example, the data input/output timing of the memory chip 701 in FIG. 15 may be different from the data input/output timing of the memory chip 701 in FIG. 16. To overcome the disparity in memory access latency of memory chips (or ranks), each of the memory chips may include components for controlling the data input/output timing.

The memory chip 800 included in the memory device may include a path changing switch 820 and buffers 811, 812, 831, and 832. The description on the path changing switch 320 and the buffers 331 and 332 given with reference to FIG. 3 may be applied to the path changing switch 820 and the buffers 831 and 832. No repeated descriptions will be provided.

The path changing switch 820 and the buffers 811, 812, 831, and 832 may be operated based on the control signals CC1 to CC5. The control signals CC1 to CC5 may be generated by the controller of the memory device. The controller may control the input/output timing of the data passing through the buffers 811, 812, 831, and 832 by using the control signals CC1 to CC3 and CC5. The controller may control the opening/closing of the path changing switch 820 by using the control signal CC4.

The controller may choose the data input/output timing of the memory chip 701 in FIG. 16 as a reference time. For example, the controller may set a first delay time of the buffer 812 as a minimum delay time. For another example, the controller may adjust (or set) the first delay time of the buffer 812 to a second delay time of the buffers 831 and 832.

The controller may adjust the data input/output timings of other memory chips than the memory chip which is used to determine the reference time. In an embodiment, the controller may adjust corresponding buffers so that data input/output timings of the memory chips in the memory device (or in the memory system) are set or adjusted to the determined reference time. For example, the controller may generate a control signal CC2 so that the data input/output timing of the memory chip 701 in FIG. 15 may be adjusted to the reference time. The memory chip 701 may delay the input/output timing of data by using the buffer 811 based on the control signal CC2.

In an embodiment, the controller may obtain a time difference between the data input/output timing of the memory chip 401 in FIG. 6 and the data input/output timing of the memory chip 701 in FIG. 16. By using the time difference, the controller may determine a reference time. For example, the controller may generate and provide control signals CC2 and CC5 so as to adjust the data input/output timing of memory chips of memory devices that are not 2R×4 type or 2R×8 type. Therefore, the memory chip 701 and other memory chips of the memory devices, that are not 2R×4 type or 2R×8 type, may have substantially the same data input/output timing.

FIG. 17 shows that the buffers 811 and 812 are disposed on an upper portion of the path changing switch 820, but the invention is not limited thereto. The buffers 811 and 812 may be disposed on other positions, such as a lower portion of the path changing switch 820 or lower portions of the buffers 831 and 832.

In an embodiment, the memory controller may include a logic circuit for performing a de-skewing operation for pins of the memory chip 800. The memory controller may control the timing of the data transmitted/received for respective pins by using the logic circuit. In this case, the memory chip 800 may not include the buffers 811 and 812.

In an embodiment, an electronic device may include a memory system and a memory controller. Though not shown in the drawings, the memory controller may not be included in the memory system. The memory system may include at least one set of plurality of memory chips (or may include at least one memory device including a set of a plurality of memory chips), to which the description on the memory controllers and the set of plurality of memory chips of FIG. 1 to FIG. 17 may be applied. The electronic device may be an SSD, a storage system (e.g., a server), or a computer system.

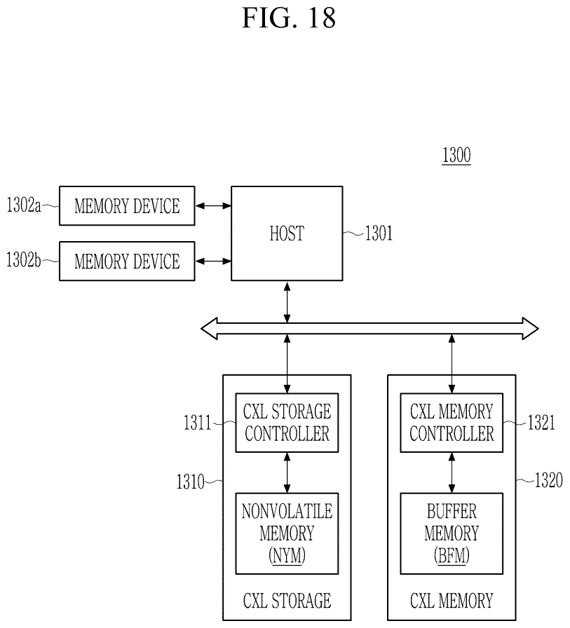

FIG. 18 shows a block diagram of a computing system to which a storage system is adapted according to an embodiment.

Referring to FIG. 18, the computing system 1300 may include a host 1301, memory devices 1302a and 1302b, a CXL storage unit 1310, and a CXL memory 1320. In an embodiment, the computing system 1300 may be included in user devices such as a personal computer, a laptop computer, a server, a media player, or a digital camera, or automotive devices such as a GPS, a black box, or a vehicle electric device. Alternatively, the computing system 1300 may be a mobile system such as a mobile phone, a smartphone, a tablet personal computer, a wearable device, a healthcare device, or an internet of things (IOT) device.

The host 1301 may control a general operation of the computing system 1300

In an embodiment, the host 1301 may be one of various types of processors such as a central processing unit (CPU), a graphics processing unit (GPU), a neural processing unit (NPU), or a data processing unit (DPU). In an embodiment, the host 1301 may include a single core processor or a multi-core processor.

The memory devices 1302a and 1302b may be used as a main memory or a system memory of the computing system 1300. In an embodiment, the memory devices 1302a and 1302b may be DRAM devices, and may have form factors of a dual in-line memory module (DIMM). However, the range of the present invention is not limited thereto, and the memory devices 1302a and 1302b may include nonvolatile memories such as a flash memory, a PRAM, a RRAM, or an MRAM.

The memory devices 1302a and 1302b may communicate with the host 1301 through a DDR interface. In an embodiment, the host 1301 may include a memory controller for controlling the memory devices 1302a and 1302b. However, the range of the present invention is not limited thereto, and the memory devices 1302a and 1302b may communicate with the host 1301 through various types of interfaces.

The description on the memory device described with FIG. 1 to FIG. 17 may be applied to the memory devices 1302a and 1302b. For example, the memory devices 1302a and 1302b may include memory chips including path changing switches and buffers. The controller in the memory devices 1302a and 1302b may generate an internal signal that corresponds to information of the memory devices 1302a and 1302b. The memory devices 1302a and 1302b may generate control signals based on the signals (e.g., CS0, CS1, etc.,) received from the internal signal and host 1301. The path changing switches and the buffers may be operated based on the control signal to thus control the path of the input/output data. Hence, data input/output rates between the host 1301 and the memory devices 1302a and 1302b may be increased.

The CXL storage unit 1310 may include a CXL storage unit controller 1311 and a nonvolatile memory NVM. The CXL storage unit controller 1311 may store data in the nonvolatile memory NVM or may transmit the data stored in the nonvolatile memory NVM to the host 1301 according to control by the host 1301. In an embodiment, the nonvolatile memory NVM may be a NAND flash memory, but the range of the present invention is not limited thereto.

The CXL memory 1320 may include a CXL memory controller 1321 and a buffer memory BFM. The CXL memory controller 1321 may store data in the buffer memory BFM or may transmit the data stored in the buffer memory BFM to the host 1301 according to control by the host 1301. In an embodiment, the buffer memory BFM may be a DRAM, but the range of the present invention is not limited thereto. The description on the memory device given with reference to FIG. 1 to FIG. 17 may be applied to the CXL memory 1320.

In an embodiment, the host 1301, the CXL storage unit 1310, and the CXL memory 1320 may share the same interface. For example, the host 1301, the CXL storage unit 1310, and the CXL memory 1320 may communicate with each other through a compute express link (CXL) interface (or IF_CXL). In an embodiment, the CXL interface (IF_CXL) may support coherency, memory access, and dynamic protocol multiplexing of an input/output (IO) protocol, and may indicate low-latency and high-bandwidth links for enabling various types of connections among accelerators, memory devices, or various electronic devices.

For example, the host 1301, the CXL storage unit 1310, and the CXL memory 1320 may communicate with each other based on various computing interfaces such as a GEN-Z protocol, an NVLink protocol, a CCIX protocol, or an Open CAPI protocol.

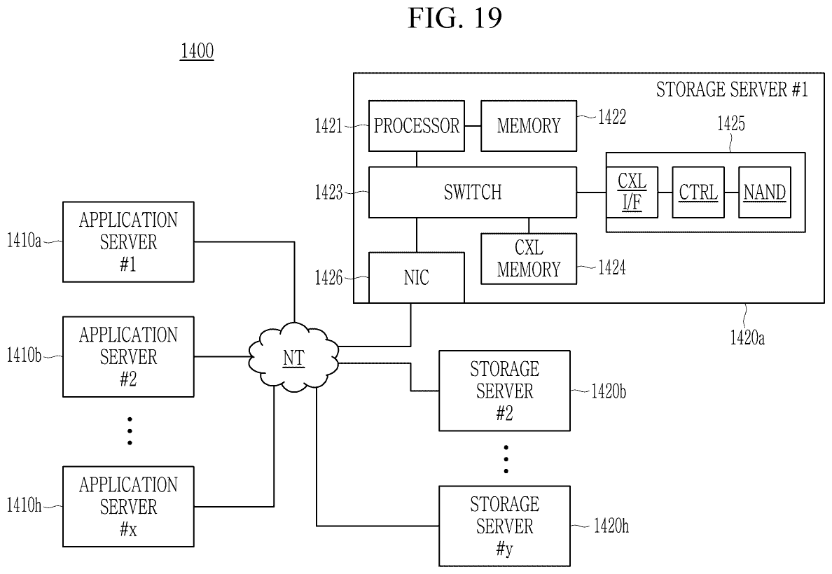

FIG. 19 shows a block diagram of a data center to which a computer system is adapted according to an embodiment. For better understanding and ease of description, no detailed descriptions on the above-noted components will be provided.

Referring to FIG. 19, the data center 1400 stores various data and provides services, and it may be referred to as a data storage center. The data center 1400 may be a system for search engines and database management, and may be a computer system used by companies such as banks or government offices. The data center 1400 may include application servers 1410a to 1410h and storage servers 1420a to 1420h. The number of the application servers and the number of the storage servers may be determined in many ways depending on embodiments, and the number of the application servers may be different from the number of the storage servers.

A configuration of the first storage server 1420a will now be described. The application servers 1410a to 1410h and the storage servers 1420a to 1420h may have similar configurations to each other, and the application servers 1410a to 1410h may communicate with the storage servers 1420a to 1420h through a network NT.

The first storage server 1420a may include a processor 1421, a memory 1422, a switch 1423, a CXL memory 1424, a storage device 1425, and a network interface card (NIC) 1426. The processor 1421 may control a generation operation of the first storage server 1420a, and may access the memory 1422 to execute instructions loaded on the memory 1422 or process the data. The memory 1422 may be a DDR SDRAM, an HMC, a DIMM, an HBM, an optane DIMM, and/or an NVDIMM. The processor 1421 and the memory 1422 may be directly connected, and the number of the processors 1421 included in one storage server 1420a and the number of the memories 1422 may be variable in many ways.

The description on the memory device given with reference to FIG. 1 to FIG. 17 may be applied to the memory 1422. For example, the memory 1422 may include memory chips including path changing switches and buffers. The controller in the memory 1422 may generate an internal signal that corresponds to information of the memory 1422. The memory 1422 may generate control signals based on the internal signal and the signals (e.g., CS0, CS1, etc.,) received from the processor 1421. The path changing switches and the buffers may be operated based on the control signals to thus control the path of the input/output data. Hence, the data input/output rates between the processor 1421 and the memory 1422 may be increased.

In an embodiment, the processor 1421 and the memory 1422 may provide a processor-memory pair. In an embodiment, the number of the processors 1421 may be different from the number of the memories 1422. The processor 1421 may include a single core processor or a multi-core processor. The description on the storage server 1420a may be similarly applied to the application servers 1410a to 1410h.

The switch 1423 may arbitrate or route communication among various constituent elements included in the first storage server 1420a. In an embodiment, the switch 1423 may be realized based on the CXL protocol.

The CXL memory 1424 may be connected to the switch 1423. The description on the memory device given with reference to FIG. 1 to FIG. 17 may be applied to the CXL memory 1424.

In an embodiment, the CXL memory 1424 may be used as a memory expander for the processor 1421. In an embodiment, the CXL memory 1424 may be allocated as an exclusive memory or a buffer memory for the storage device 1425.

The storage device 1425 may include an CXL interface circuit (CXL_IF), a controller (CTRL), and a NAND flash (NAND). The controller (CTRL) may also be referred to as a CXL controller. The storage device 1425 may store data according to a request by the processor 1421 or may output the stored data. The number of the storage devices 1425 included in the storage server 1420a may be diverse depending on embodiments.

The network interface card (NIC) 1426 may be connected to the switch 1423. The NIC 1426 may communicate with other storage servers 1420b to 1420h or other application servers 1410a to 1410h through the network NT.

In an embodiment, the NIC 1426 may include a network interface card, a network adapter, etc. The NIC 1426 may be connected to the network NT by a wired interface, a wireless interface, a Bluetooth interface, an optical interface, etc. The NIC 1426 may include an internal memory, a digital signal processor (DSP), a host bus interface, etc., and may be connected to the processor 1421 and/or the switch 1423 through the host bus interface. In an embodiment, the NIC 1426 may be combined with at least one of the processor 1421, the switch 1423, and the storage device 1425.

In an embodiment, the network NT may be realized by using a fiber channel (FC) or an Ethernet. In this instance, the FC is a medium used in high-rate data transmission, and an optical switch for providing high performance and high availability may be used. The storage servers may be provided as a pile storage, a block storage, or an object storage according to an access method of the network NT.

In an embodiment, the network NT may be a storage exclusive network such as a storage area network (SAN). For example, the SAN may be a FC-SAN using a FC network and realized according to a FC Protocol (FCP). For another example, the SAN may be an IP-SAN using a TCP/IP network and realized according to an iSCSI (SCSI over TCP/IP or Internet SCSI) protocol. In an embodiment, the network NT may be a general network such as the TCP/IP network. For example, the network NT may be realized according to the protocol such as a FC over Ethernet (FCoE), a network attached storage (NAS), and an NVMe over Fabrics (NVMe-oF).

In an embodiment, at least one of the application servers 1410a to 1410h may store the data requested to be stored by a user or a client to one of the storage servers 1420a to 1420h through the network NT. At least one of the application servers 1410a to 1410h may obtain the data requested to be read by the user or the client from one of the storage servers 1420a to 1420h through the network NT. For example, at least one of the application servers 1410a to 1410h may be realized with a web server or a database management system (DBMS).

In an embodiment, at least one of the application servers 1410a to 1410h may access the memory, the CXL memory, or the storage device included in another application server through the network NT, or may access the memories, the CXL memories, or the storage devices included in the storage servers 1420a to 1420h through the network NT. Hence, at least one of the application servers 1410a to 1410h may perform various operations on the data stored in other application servers and/or storage servers. For example, at least one of the application servers 1410a to 1410h may perform an instruction for shifting or copying data among other application servers and/or storage servers. In this instance, the data may be moved to the memory or the CXL memory of the application servers from the storage device of the storage servers through the memories of the storage servers or CXL memories, or directly. The data moved through the network may be data encoded for security or privacy.

In an embodiment, the storage device included in at least one of the application servers 1410a to 1410h and the storage servers 1420a to 1420h may receive the CXL memory included in at least one of the application servers 1410a to 1410h and the storage servers 1420a to 1420h as an exclusive region, and the storage device may use the received exclusive region as a buffer memory (i.e., may store map data). For example, the storage device 1425 stored in the storage server 1420a may receive the CXL memory included in another storage server (e.g., 1420h), and may access the CXL memory included in another storage server (e.g., 1420h) through the switch 1423 and the NIC 1426. In this case, the map data on the storage device 1425 of the first storage server 1420a may be stored in the CXL memory of another storage server 1420h. For example, the storage devices and the CXL memories of the data center 1400 according to an aspect of the present invention may be connected and realized in many ways.

In an embodiment, the respective component or combinations of two or more components described with reference to FIG. 1 to FIG. 19 may be realized with digital circuits, programmable or non-programmable logic devices or arrays, and application specific integrated circuits (ASIC).

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A memory device comprising:
a memory cell array configured to store data;
a plurality of data lines configured to transmit the data;
path changing switches connected to the plurality of data lines; and
a controller configured to receive a first selection signal and a second selection signal, which are rank selecting signals from a memory controller,
wherein the controller is configured to control opening/closing of the path changing switches based on the first selection signal and the second selection signal.

2. The memory device of claim 1, wherein:
the controller generates a first signal indicating a number of ranks in the memory device,
the controller generates a second signal indicating a size of input/output data, and
the path changing switches are configured to be opened/closed by the controller based on the first selection signal, the second selection signal, the first signal, and the second signal.

3. The memory device of claim 2, wherein the controller is configured to generate the first signal to have a first-level in order to configure the memory device with a dual rank.

4. The memory device of claim 2, wherein the controller is configured to generate the second signal of a first-level in order to configure the memory device to inputs/output 8-bit data.

5. The memory device of claim 2, wherein the controller generates the first signal based on the first selection signal and the second selection signal.

6. The memory device of claim 2, wherein the controller generates the first signal and the second signal based on serial presence detect (SPD) information.

7. The memory device of claim 1, wherein:
the plurality of data lines include first data lines and second data lines,
the controller generates a first control signal, a second control signal and a third control signal, and
the path changing switches include:
a first path changing switch connected to the first data lines and configured to be opened/closed based on the first control signal;
a second path changing switch connected to the second data lines and configured to be opened/closed based on the second control signal; and
a third path changing switch connected to the first data lines and the second data lines and configured to be opened/closed based on the third control signal.

8. The memory device of claim 7, wherein
the controller generates a first signal indicating whether the memory device has a dual rank configuration and a second signal indicating a size of input/output data, and
the first control signal, the second control signal, and the third control signal are generated by the controller based on the first selection signal, the second selection signal, the first signal, and the second signal.

9. The memory device of claim 8, wherein the controller includes logic circuits configured to generate the first control signal, the second control signal, and the third control signal based on the first selection signal, the second selection signal, the first signal, and the second signal.

10. The memory device of claim 9, wherein the logic circuits include an inverter, an AND gate, an OR gate, and an XOR gate.

11. The memory device of claim 8, further comprising
a first buffer connected to the first data lines and configured to be operated based on a fourth control signal; and
a second buffer connected to the second data lines and configured to be operated based on a fifth control signal,
wherein the controller further generates the fourth control signal and the fifth control signal based on the second selection signal, the first signal, and the second signal.

12. A memory device comprising:
a memory cell array configured to store data;
a plurality of data pins configured to input/output the data, wherein the plurality of data pins includes first data pins and second data pins;
first data lines connecting the first data pins and the memory cell array;
second data lines connecting the second data pins and the memory cell array; and
a first path changing switch connected to the first data lines and the second data lines and adjusting an input/output path of the data based on a first control signal.

13. The memory device of claim 12, further comprising
a controller configured to generate a first control signal based on a selection signal received from a memory controller.

14. The memory device of claim 13, wherein the controller generates the first control signal of a first-level based on a first rank selecting signal and generates a second control signal of a second-level based on a second rank selecting signal.

15. The memory device of claim 12, further comprising
a second path changing switch connected to the first data lines and the memory cell array and configured to be opened/closed based on a second control signal; and
a third path changing switch connected to the second data lines and the memory cell array and configured to be opened/closed based on a third control signal.

16. The memory device of claim 12, further comprising a buffer connected between the plurality of data pins and the first and second data lines and configured to be operated based on a second control signal.

17. A memory device comprising:
a plurality of memory chips configured to input/output data with a predetermined size and including path changing switches connected to data lines; and
a controller configured to determine a data input/output path in the plurality of memory chips by opening/closing the path changing switches based on a first rank selecting signal and a second rank selecting signal.

18. The memory device of claim 17, wherein
the plurality of memory chips includes a first set of memory chips and a second set of memory chips,
the plurality of memory chips are configured for the memory device to be operated as 2R×4,
the first set of memory chips is included in a first rank,
the second set of memory chips is included in a second rank,
each of the first set of memory chips is connected to a corresponding one of the second set of memory chips, and
the controller inputs/outputs data by using the second set of memory chips based on the first rank selecting signal, and inputs/outputs data by using the first set of memory chips and the second set of memory chips based on the second rank selecting signal.

19. The memory device of claim 18, wherein
each of the first and second sets of memory chips has data pins, and
each of the data pins of the first set of memory chips is connected to a corresponding one of the data pins of the second set of memory chips.

20. The memory device of claim 17, wherein:
the plurality of memory chips includes a first set of memory chips and a second set of memory chips,
the plurality of memory chips are configured for the memory device to be operated as 2R×8,
each of the plurality of memory chips input/output 4-bit data,
the first set of memory chips is included in a first rank,
the second set of memory chips is included in a second rank, and
the controller inputs/outputs data by using first a first data path based on the first rank selecting signal, and inputs/outputs data by using a second data path based on the second rank selecting signal.
